(19) United States
(12) Patent Application Publication
(10) Pub. No.: US 2012/0118616 A1
(43) Pub. Date: May 17, 2012

(54) NEGATIVE PHOTOSENSITIVE RESIN COMPOSITION, POLYIMIDE RESIN FILM USING SAME, AND FLEXIBLE PRINTED CIRCUIT BOARD

(76) Inventors: Hideaki Saito, Osaka-shi (JP); Masaya Kakimoto, Osaka-shi (JP); Hiroshi Ueda, Kouga-shi (JP); Sumito Uehara, Kouga-shi (JP)

(21) Appl. No.: 13/387,610

(22) PCT Filed: Jul. 21, 2010
(86) PCT No.: PCT/JP2010/062222

§ 371 Date: Jan. 27, 2012

(30) Foreign Application Priority Data
Jul. 27, 2009 (JP) 2009-173940
Mar. 23, 2010 (JP) 2010-065968

(51) Int. Cl. H05K 1/03; G03F 7/004

(52) U.S. Cl. 174/254; 430/270.1

(57) ABSTRACT

A negative photosensitive resin composition contains a polyimide precursor resin obtained by condensation polymerization of a carboxylic anhydride component containing an aromatic tetracarboxylic dianhydride and a diamine component containing an aromatic diamine, a photopolymerizable monomer, and a photopolymerization initiator, wherein a compound having a photoreactive functional group and a glycidyl group is contained as the photopolymerizable monomer in an amount of 0.05% to 15% by weight relative to the total solid content of the negative photosensitive resin composition. Accordingly, a negative photosensitive resin composition is provided in which non-exposed areas have excellent solubility in a developing solution and degradation of the film located in exposed areas, the degradation being caused by the developing solution, is suppressed. Also provided are a printed circuit board and a polyimide film using the negative photosensitive resin composition.

### TECHNICAL FIELD

The present invention relates to a negative photosensitive resin composition suitable for use in, for example, the formation of a protective film of a flexible printed circuit board, a polyimide resin film using the negative photosensitive resin composition, and a flexible printed circuit board.

### BACKGROUND ART

Polyimide resins have excellent heat resistance and exhibit good electrical insulating property, and thus are used as a base, an interlayer adhesive, a cover lay (protective film), and the like of printed circuit boards. In addition, with a realization of fine wiring, imparting of photosensitivity to a polyimide resin has been studied in order to form a fine pattern of the polyimide resin used as a protective film. A coating film made of a photosensitive resin composition containing a polyimide resin is formed on a base having wiring thereon, and the base is then irradiated with ultraviolet light or the like through a mask so as to change a property of exposed areas. Thus, only the exposed areas (positive) or only non-exposed areas (negative) can be removed to form a pattern.

As a method for imparting photosensitivity to a polyimide precursor, a method is used in which a compound having a photoreactive functional group and an amino group is introduced into a polyimide precursor by an ionic bond. PTL 1 discloses a negative photosensitive material containing a polyimide precursor (polyamic acid), a compound (photopolymerizable monomer) having a carbon-carbon double bond that can be either dimerized or polymerized by actinic rays and an amino group or a quaternized salt thereof, and, as required, a sensitizer, a photoinitiator, and a comonomer. When this photosensitive material is irradiated with actinic rays through a pattern, in exposed areas, the photopolymerizable monomer is polymerized, and the amino group of the photopolymerizable monomer and a carboxyl group of the polyimide precursor form an ionic bond, thereby decreasing solubility in a solvent. Subsequently, non-exposed areas are removed by being dissolved in a developing solution to form a pattern. The pattern is then cured by heating to obtain a polyimide film.

Another method for imparting photosensitivity to a polyimide precursor includes introducing a photoreactive functional group into a polyimide precursor by an ester bond. PTL 2 discloses such a photosensitive polyimide precursor.

PTL 3 discloses a circuit board and a suspension substrate with a circuit, the circuit board and suspension substrate including a protective film made of a negative photosensitive polyimide resin. The suspension substrate with a circuit includes a metal foil base made of stainless steel or the like, an insulating layer provided on the base, a pattern circuit of a conductor layer made of a metal such as copper, the pattern circuit being provided on the insulating layer, and an insulating layer covering the pattern circuit. In PTL 2, a negative photosensitive polyimide resin is used as the insulating layer provided on the metal foil base and the insulating layer covering the conductor layer.

### SUMMARY OF INVENTION

### Technical Problem

In the case where a negative photosensitive resin composition is used, a polar organic solvent is used as a developing solution in a developing step of dissolving a polyimide precursor located in non-exposed areas to remove the polyimide precursor. The polyimide precursor located in exposed areas does not dissolve in the developing solution, forms a pattern, and remains. However, because of a high solubility of the polyimide precursor in the polar organic solvent, also in the polyimide precursor located in the exposed areas, degradation of a film, such as swelling of the film, formation of cracks, and a decrease in the film thickness tends to be caused by the developing solution. In order to obtain a satisfactory developing property, it is necessary that the non-exposed areas rapidly dissolve without remaining as a residue and that degradation of the film located in the exposed areas be prevented.

Although the ester bond-type polyimide precursor has a relatively good developing property, the polyimide precursor has a problem in that a design change is not easily performed because a multistep reaction is necessary for the synthesis thereof Although the ionic bond-type polyimide precursor is easily synthesized, a bonding strength between the photoreactive functional group and the polyimide precursor is weak. Accordingly, from the standpoint of the structure, exposed areas that remain as a film after the exposure and development also tend to be swollen by a developing solution. As a result, problems such as a decrease in the adhesiveness to a base, a phenomenon of the film thickness, and the formation of cracks may occur.

In view of the above problems, an object of the present invention is to provide a negative photosensitive resin composition in which non-exposed areas have excellent solubility in a developing solution, and degradation of a film located in exposed areas, the degradation being caused by the developing solution, is suppressed, a polyimide resin film using the same, and a printed circuit board.

### Solution to Problem

The present invention provides a negative photosensitive resin composition containing a polyimide precursor resin obtained by condensation polymerization of a carboxylic anhydride component containing an aromatic tetracarboxylic dianhydride and a diamine component containing an aromatic diamine; at least one photopolymerizable monomer; and a photopolymerization initiator, wherein a compound having a photoreactive functional group and a glycidyl group is contained as the at least one photopolymerizable monomer in an amount of 0.05% to 15% by weight relative to the total solid content of the negative photosensitive resin composition (first invention of the present application).

The compound having a photoreactive functional group and a glycidyl group is polymerized and bonded to a carboxyl group of the polyimide precursor by exposure. This action can improve the degree of cross-linking of the polyimide precursor in exposed areas to reduce degradation by a developing solution.

Note that the term “total solid content of the negative photosensitive resin composition” refers to the total amount of solid content of all materials including the polyimide precursor resin, the at least one photopolymerizable monomer, the photopolymerization initiator, and other additives. The content of the compound having a photoreactive functional group and a glycidyl group is 0.05% to 15% by weight relative to the total solid content of the negative photosensitive resin composition. However, the content is more preferably in the range of 0.05% to 10% by weight.

A compound having a photoreactive functional group and an amino group is preferably contained as the at least one photopolymerizable monomer (second invention of the present application). Only the compound having a photoreactive functional group and a glycidyl group may be used as the at least one photopolymerizable monomer. However, the compound having a photoreactive functional group and a glycidyl group has a high reactivity of the glycidyl group. Therefore, addition of a large amount of such a compound tends to cause gelation of the negative photosensitive resin composition. By using an ionic-bond type photopolymerizable monomer, such as a compound having a photoreactive functional group and an amino group, in combination, the photopolymerizable monomer can be incorporated in the resin composition in a sufficient amount relative to the carboxyl groups of the polyimide precursor resin.

The compound having a photoreactive functional group and a glycidyl group is preferably at least one selected from the group consisting of glycidyl methacrylate, glycidyl acrylate, allyl glycidyl ether, and 4-hydroxybutyl acrylate glycidyl ether (third invention of the present application). Because of high reactivity of these compounds, the degree of cross-linking of the polyimide precursor in exposed areas can be further improved.

Any polyimide precursor resin can be used as long as the polyimide precursor resin is obtained by condensation polymerization of a carboxylic anhydride component containing an aromatic tetracarboxylic dianhydride and a diamine component containing an aromatic diamine However, a fluorinated monomer is preferably contained as the diamine component in an amount of 30% by mole or more and 70% by mole or less relative to the total amount of the diamines (fourth invention of the present application). The use of an appropriate amount of a fluorinated monomer can improve the solubility of non-exposed areas in a developing solution during patterning (development) to reduce the developing time. Conversely, in this case, the film in exposed areas tends to degrade. In such a system, by using the compound having a photoreactive functional group and a glycidyl group as a photopolymerizable monomer, it is possible to reduce degradation of the film in the exposed areas by the developing solution.

The present invention also provides a polyimide resin film obtained by applying any of the above-described photosensitive resin compositions onto a base, and curing the photosensitive resin composition by heating (fifth invention of the present application). A polyimide resin film having a desired pattern can be formed by applying a photosensitive resin composition, subsequently drying a solvent, prior to curing by heating, exposing the photosensitive resin composition through a mask and performing a development with a developing solution. The polyimide precursor (polyamic acid) resin is converted to a polyimide resin in the step of curing by heating.

Furthermore, the present invention provides a polyimide resin film obtained by the above production method and having a thermal expansion coefficient of 10 ppm/° C. or more and 30 ppm/° C. or less. The present invention also provides a flexible printed circuit board including the polyimide resin film as a protective film.

By controlling the thermal expansion coefficient of the polyimide resin film to be 10 ppm/° C. or more and 30 ppm/° C. or less, the thermal expansion coefficient of the polyimide resin film can be made close to the thermal expansion coefficients of metals such as stainless steel and copper. Thus, in a flexible printed circuit board including the polyimide resin film and these metals in combination, warpage due to a temperature change can be reduced. Such a flexible printed circuit board is particularly preferably used as a substrate for a suspension used in a hard disk drive. Note that the thermal expansion coefficient can be measured with a thermomechanical analyzer (TMA) and is defined as an average in the range of 50° C. to 150° C.

### Advantageous Effects of Invention

According to the present invention, it is possible to obtain a negative photosensitive resin composition in which non-exposed areas have excellent solubility in a developing solution, and degradation of a film located in exposed areas, the degradation being caused by the developing solution, is suppressed. Furthermore, a polyimide resin film whose degradation is suppressed can be obtained by using this negative photosensitive resin composition.

### Description of Embodiments

A polyimide precursor resin (polyamic acid) contained in a negative photosensitive resin composition of the present invention is obtained by condensation polymerization of an aromatic tetracarboxylic dianhydride component and a diamine component containing an aromatic diamine. This condensation polymerization reaction can be performed under the same conditions as those for the synthesis of existing polyimides. As a solvent of the negative photosensitive resin composition of the present invention, a polar solvent such as N-methyl-2-pyrroridone or γ-butyrolactone is preferably used.

Examples of the aromatic tetracarboxylic dianhydride include 3,4,3′,4′-biphenyltetracarboxylic dianhydride (BPDA), pyromellitic dianhydride (PMDA), 3,3′,4,4′-benzophenonetetracarboxylic dianhydride, 4,4′-oxydiphthalic dianhydride, 3,3′,4,4′-diphenylsulfonetetracarboxylic dianhydride, bicyclo(2.2.2)-oct-7-ene-2,3,5,6-tetracarboxylic dianhydride, 1,2,4,5-cyclohexanetetracarboxylic dianhydride, 2,2-bis(3,4-dicarboxyphenyl)hexafluoropropane dianhydride, and 5-(2,5-dioxotetrahydrofuryl)-3-methyl-3-cyclohexene-1,2-dicarboxylic dianhydride.

Among these, 3,4,3′,4′-biphenyltetracarboxylic dianhydride (BPDA) represented by formula (I) below is preferable because this compound has a rigid structure having a biphenyl skeleton and can decrease the thermal expansion coefficient of the resulting polyimide resin. The content of BPDA is preferably 50% by mole or more relative to the total amount of aromatic tetracarboxylic dianhydride component. With this monomer configuration, the content of a monomer having a biphenyl skeleton, the monomer being a rigid component, can be increased, and the thermal expansion coefficient of the polyimide can be decreased.

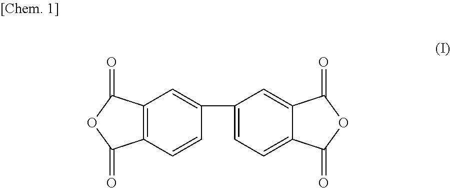

The polyimide precursor resin is obtained by condensation polymerization of at least one aromatic tetracarboxylic dianhydride and two or more diamines. In this polyimide precursor resin, two or more monomers each having a biphenyl skeleton are preferably contained as the diamines or the at least one aromatic tetracarboxylic dianhydride, the content of the monomers having a biphenyl skeleton is preferably 50% by mole or more relative to the total amount of the at least one aromatic tetracarboxylic dianhydride and the diamines, and a diamine having a tetramethyldisiloxane skeleton is preferably contained as one of the diamines in an amount of 0.5% by mole or more and 5% by mole or less relative to the total amount of diamines.

By using two or more monomers having a biphenyl skeleton, the monomers being rigid components, and controlling the content thereof to be 50% by mole or more, the thermal expansion coefficient can be decreased, and a satisfactory developing property can be obtained. In addition, by introducing a disiloxane skeleton into the polymer main chain using a small amount of a diamine having a flexible tetramethyldisiloxane skeleton, the adhesiveness to a substrate can be improved and transparency (i-line transparency) of the resulting polyimide resin can be improved. Each of the monomers having a biphenyl skeleton may be either an aromatic tetracarboxylic dianhydride or a diamine. However, the monomers having a biphenyl skeleton are preferably used in both an aromatic tetracarboxylic dianhydride and a diamine.

Examples of the diamines include 2,2′-dimethyl-4,4′-diaminobiphenyl (mTBHG), 2,2′-bis(trifluoromethyl)-4,4′-diaminobiphenyl (TFMB), 2,2′-bis(4-aminophenyl)hexafluoropropane (Bis-A-AF), paraphenylenediamine (PPD), 4,4′-diaminodiphenyl ether (ODA), 3,3′-dihydroxy-4,4′-diaminobiphenyl, and 4,4′-dihydroxy-3,3′-diaminobiphenyl.

Among these, 2,2′-dimethyl-4,4′-diaminobiphenyl (mTBHG) represented by formula (II) and 2,2′-bis(trifluoromethyl)-4,4′-diaminobiphenyl (TFMB) represented by formula (III) are each have a rigid structure having a biphenyl skeleton, and thus are preferable from the standpoint that the thermal expansion coefficient of the resulting polyimide resin can be decreased, and a satisfactory developing property can be obtained.

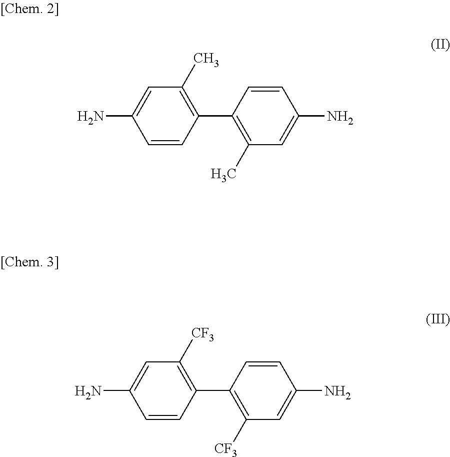

The monomers having a biphenyl skeleton each may be either an aromatic tetracarboxylic dianhydride or a diamine, and are preferably contained in an amount of 50% by mole or more relative to the total of the monomer components (the total amount of carboxylic anhydride component and diamine component). The content of monomers having a biphenyl skeleton is more preferably 70% or more.

Furthermore, it is necessary to incorporate, as one of the diamines, a diamine having a tetramethyldisiloxane skeleton in an amount of 0.5% by mole or more and 5% by mole or less relative to the total of the diamine component. By incorporating a small amount of the diamine having a tetramethyldisiloxane skeleton, the adhesiveness of the polyimide resin is improved. If the amount of diamine having a tetramethyldisiloxane skeleton is less than 0.5% by mole, the above advantage cannot be sufficiently achieved. On the other hand, if the amount exceeds 5% by mole, the thermal expansion coefficient of the polyimide resin increases.

The diamine having a tetramethyldisiloxane skeleton is a compound having a siloxane skeleton and having two primary amino groups at the ends thereof For example, a compound represented by formula (IV) below is widely used.

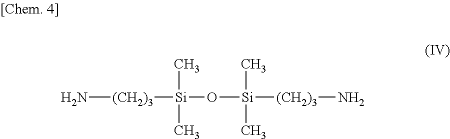

In addition to the above compound, compounds represented by structural formulae below are also exemplified.

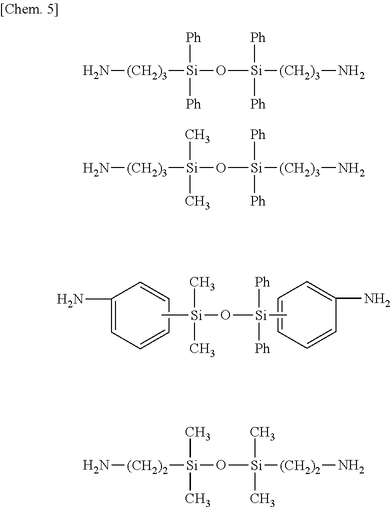

Furthermore, as the diamines or the aromatic tetracarboxylic dianhydride, a fluorinated monomer is preferably incorporated in an amount of 30% by mole or more and 70% by mole or less relative to the total of the diamine component. The incorporation of the fluorinated monomer can improve transparency (optical transparency) of the polyimide resin. Furthermore, since the solubility of the polyimide resin in a developing solution increases, the developing property in thick films improves. However, when the content of the fluorinated monomer is excessively large, the cost is increased and mechanical and physical properties of the resulting insulating film decrease. Therefore, the content of the fluorinated monomer is preferably 70% by mole or less.

Examples of the fluorinated monomer include the above-mentioned 2,2′-bis(trifluoromethyl)-4,4′-diaminobiphenyl (TFMB) and 2,2′-bis(4-aminophenyl)hexafluoropropane (BIS-A-AF) represented by formula (VI).

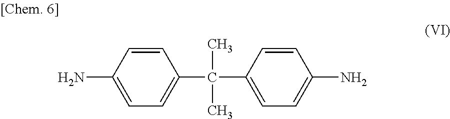

The polyimide precursor resin contained in the photosensitive resin composition of the present invention preferably has a weight-average molecular weight in the range of 20,000 to 400,000 measured by gel permeation chromatography (GPC). When the weight-average molecular weight exceeds this range, problems such as degradation of a printing property of the composition and generation of a residue at the time of the development tend to occur. On the other hand, when the weight-average molecular weight is lower than this range, there may be problems in that the film is degraded at the time of the development, and that the mechanical strength of the coating film becomes insufficient, for example.

A photopolymerizable monomer contained in the photosensitive resin composition of the present invention is a monomer having a photoreactive functional group which is cross-linked by irradiation of (exposure with) X rays, an electron beam, ultraviolet light, or the like. In the present invention, a compound having a photoreactive functional group and a glycidyl group in the same molecule is used as all of or some of the photopolymerizable monomers. Examples of the usable compounds having a photoreactive functional group and a glycidyl group include glycidyl (meth)acrylates such as glycidyl methacrylate and glycidyl acrylate, allyl glycidyl ether, and 4-hydroxybutyl acrylate glycidyl ether.

Among the above compounds, allyl glycidyl ether is particularly preferably used because both a high adhesive strength to a base (copper foil) and a good developing property can be achieved. In order to improve the developing property, it is necessary to reduce the amount of residue generated at the time of the development, that is, it is necessary to satisfactorily separate the polyimide precursor from the base (copper foil). In this case, however, problems such as generation of cracks in the resulting polyimide film after curing and lifting of the coating polyimide film tend to occur. By using allyl glycidyl ether, the developing property can be improved and the adhesive strength between the polyimide film after curing and the base can be satisfactorily maintained.

Furthermore, a compound having an amino group and a photoreactive functional group such as an unsaturated double bond is preferably contained as a photopolymerizable monomer. Examples of such a compound include N,N-dimethylaminoethyl methacrylate, N,N-dimethylaminoethyl acrylate, N,N-diethylaminoethyl methacrylate, N,N-diethylaminoethyl acrylate, N,N-dimethylaminomethyl methacrylate, N,N-dimethylaminopropyl methacrylate, N,N-dimethylaminomethyl acrylate, N,N-dimethylaminopropyl acrylate, acrylamide, methacrylamide, N-methylmethacrylamide, N-methylacrylamide, N-ethylmethacrylamide, N-ethylacrylamide, N-isopropylmethacrylamide, N-isopropylacrylamide, N-butylmethacrylamide, N-butylacrylamide, diacetone acrylamide, diacetone methacrylamide, N-cyclohexylmethacrylamide, N-cyclohexylacrylamide, N-methylolacrylamide, acryloylmorpholine, methacryloylmorpholine, acryloylpiperidine, methacryloylpiperidine, crotonamide, N-methylcrotonamide, N-isopropylcrotonamide, N-butylcrotonamide, allylamide acetate, and allylamide propionate. The photopolymerizable monomer is preferably incorporated in an amount in the range of 1 to 1.5 equivalents relative to the carboxyl group of the polyimide precursor resin.

Regarding a photopolymerization initiator contained in the photosensitive resin composition of the present invention, α-aminoketone-type initiators are preferably used as i-line (wavelength: 365 nm)-absorbing initiators, and metallocene initiators such as titanocene compounds are preferably used as g-line (wavelength: 436 nm)-absorbing initiators. A satisfactory developing property can be obtained by incorporating any of these initiators in an amount of 0.1% to 10% by weight relative to the solid content of the polyimide precursor resin.

The negative photosensitive resin composition of the present invention can be obtained by mixing the polyimide precursor resin, the at least one photopolymerizable monomer, and the polymerization initiator described above. Furthermore, the photosensitive resin composition of the present invention may contain various additives, as needed. As for the additives, examples of dyes and pigments for improving visibility during development include phenolphthalein, Phenol Red, Nile Red, Pyrogallol Red, Pyrogallol Violet, Disperse Red 1, Disperse Red 13, Disperse Red 19, Disperse Orange 1, Disperse Orange 3, Disperse Orange 13, Disperse Orange 25, Disperse Blue 3, Disperse Blue 14, Eosin B, Rhodamine B, quinalizarin, 5-(4-dimethylaminobenzylidene)rhodanine, aurintricarboxylic acid, aluminon, alizarin, pararosaniline, emodin, thionine, Methylene Violet, Pigment Blue, and Pigment Red. Examples of additives for improving acceleration of the dissolution of non-exposed areas include benzenesulfonamide, N-methylbenzenesulfonamide, N-ethylbenzenesulfonamide, N,N-dimethylbenzenesulfonamide, N-n-butylbenzenesulfonamide, N-t-butylbenzenesulfonamide, N,N-di-n-butylbenzenesulfonamide, benzenesulfonanilide, N,N-diphenylbenzenesulfonamide, N-p-tolyl-benzenesulfonamide, N-o-tolyl-benzenesulfonamide, N-m-tolyl-benzenesulfonamide, N,N-di-p-tolyl-benzenesulfonamide, p-toluenesulfonamide, N-methyl-p-toluenesulfonamide, N-ethyl-p-toluenesulfonamide, N,N-dimethyl-p-toluenesulfonamide, N-n-butyl-p-toluenesulfonamide, N-t-butyl-p-toluenesulfonamide, N,N-di-n-butyl-p-toluenesulfonamide, N-phenyl-p-toluenesulfonamide, N,N-diphenyl-p-toluenesulfonamide, N-p-tolyl-p-toluenesulfonamide, N-m-tolyl-p-toluenesulfonamide, N,N-di-p-tolyl-p-toluenesulfonamide, N,N-di-m-tolyl-p-toluenesulfonamide, o-toluenesulfonamide, N-methyl-o-toluenesulfonamide, N-ethyl-o-toluenesulfonamide, N,N-dimethyl-o-toluenesulfonamide, N-n-butyl-o-toluenesulfonamide, N-t-butyl-o-toluenesulfonamide, N,N-di-n-butyl-o-toluenesulfonamide, N-phenyl-o-toluenesulfonamide, N,N-diphenyl-o-toluenesulfonamide, N-p-tolyl-o-toluenesulfonamide, N-m-tolyl-o-toluenesulfonamide, N,N-di-p-tolyl-o-toluenesulfonamide, N,N-di-m-tolyl-o-toluenesulfonamide, naphthalenesulfonamide, N-methylnaphthalenesulfonamide, N-ethyl naphthalenesulfonamide, N,N-dimethyl naphthalenesulfonamide, N-n-butyl naphthalenesulfonamide, N-t-butyl naphthalenesulfonamide, N,N-di-n-butyl naphthalenesulfonamide, N-phenyl naphthalenesulfonamide, N,N-diphenyl naphthalenesulfonamide, N-p-tolyl naphthalenesulfonamide, N-o-tolyl naphthalenesulfonamide, N-m-tolyl naphthalenesulfonamide, N,N-di-p-tolyl naphthalenesulfonamide, N,N-di-m-tolyl naphthalenesulfonamide, 2,3-dimethylbenzenesulfonamide, N-methyl-2,3-dimethylbenzenesulfonamide, N-n-butyl-2,3-dimethylbenzenesulfonamide, p-ethylbenzenesulfonamide, N-methyl-p-ethylbenzenesulfonamide, N-ethylbenzenesulfonamide, N,N-dimethylbenzenesulfonamide, and N-n-butyl-p-ethylbenzenesulfonamide.

Note that an ester bond-type polyimide precursor resin may also be used as the polyimide precursor resin contained in the negative photosensitive resin composition of the present invention. In such a case, the compound having a photoreactive functional group and a glycidyl group functions as a cross-linking agent to improve the degree of cross-linking of the polyimide precursor resin in exposed areas. Thus, degradation of a film by a developing solution can be prevented.

A polyimide resin film is obtained by the steps of applying the negative photosensitive resin composition onto a base, removing a solvent by heating the resulting film, exposing the film, from which the solvent has been removed, through a mask, developing the film using a developing solution, and curing the film after the development by heating.

The photosensitive resin composition can be applied by a general method such as screen printing, spin coating, or doctor knife coating. The subsequent steps can also be conducted as in the case where an existing negative photosensitive resin composition is used.

The polyimide resin film obtained in this manner can have a large thickness, and the thickness of the film at the time of the development can be 20 μm or more. Furthermore, the film can have a thermal expansion coefficient of 10 ppm/° C. or more and 30 ppm/° C. or less. The thermal expansion coefficient of stainless steel is about 17 ppm/° C. and the thermal expansion coefficient of copper is about 19 ppm/° C. Accordingly, by controlling the thermal expansion coefficient of the polyimide resin film to be in the range of 10 ppm/° C. to 30 ppm/° C., the thermal expansion coefficient of the polyimide resin film can be made close to the thermal expansion coefficients of the metals. Thus, when the polyimide resin film and these metals are used in combination, it is possible to obtain a product in which warpage due to a temperature change is reduced.

The present invention also provides a flexible printed circuit board including the above polyimide resin film as a protective film. An example thereof is a single-sided flexible printed circuit board including a polyimide base, a conductor wiring made of a metal such as copper and disposed on a surface of the polyimide base, and the above-described polyimide resin film functioning as a cover lay film (protective film) and disposed on the conductor wiring. Another example thereof is a suspension substrate with a circuit, the suspension substrate including a metal foil base made of stainless steel or the like, an insulating layer made of polyimide or the like and disposed on the metal foil base, a conductor wiring (circuit) made of a metal such as copper and disposed on the insulating layer, and the above-described polyimide resin film functioning as a protective film and disposed on the conductor wiring. In this case, the above-described polyimide resin film can also be used as the insulating layer disposed on the metal foil substrate. This suspension substrate with a circuit is used as a substrate for a suspension used in a hard disk drive.

Next, best modes for carrying out the invention will be described by way of Examples. In Examples, in particular, a description will be made of ionic bond-type negative photosensitive resin compositions, but the description does not limit the scope of the present invention.

### EXAMPLES

### Example 1

First, 35.5 g (120 mmol) of 2,2′-dimethyl-4,4′-diaminobiphenyl (mTBHG) and 19.4 g (180 mmol) of p-phenylenediamine (PPD) were dissolved in 700 g of N-methylpyrrolidone, and 44.2 g (150 mmol) of 3,4,3′,4′-biphenyltetracarboxylic dianhydride

(BPDA) and 32.7 g (150 mmol) of pyromellitic dianhydride (PMDA) were then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 16.5%. Dimethylaminomethyl methacrylate, which is a photopolymerizable monomer, was mixed with the varnish in an amount of 1.2 equivalents relative to the carboxylic acid of the polyamic acid, and glycidyl methacrylate was mixed with the varnish in an amount of 2% relative to the total solid content of the varnish. In addition, as a polymerization initiator, 2-benzyl-2-(dimethylamino)-1-[4-(4-morpholinyl)phenyl]-1-butanone (molar extinction coefficient at a wavelength of 365 nm: 1,500) was mixed with the varnish in an amount of 4% relative to the total solid content of the varnish. Thus, a negative photosensitive resin composition was prepared.

The negative photosensitive resin composition was applied onto a copper foil having a thickness of 40 μm by a spin-coating method, and was then dried by heating at 90° C. for 30 minutes to form a photosensitive polyimide precursor film having a thickness of 20 μm. Subsequently, the film was irradiated with ultraviolet light through a negative test pattern at a light exposure of 1,000 mJ/cm², and post-baking was then performed at 105° C. for 10 minutes. Subsequently, development was performed at 30° C. using an organic solvent developing solution. The film on the copper foil was sufficiently washed with distilled water, and was then forcibly dried in a nitrogen stream. Subsequently, heat treatment was performed at 120° C. for 30 minutes, at 220° C. for 30 minutes, and at 340° C. for 60 minutes in a nitrogen atmosphere to imidize the polyimide precursor. As a result, a polyimide resin film in which a film loss did not substantially occur and which maintained a satisfactory development pattern was obtained. The polyimide film after curing had a thermal expansion coefficient of 16 ppm/° C. and a film-remaining ratio of 89%. The thermal expansion coefficient was determined by thermomechanical analysis (TMA) (a tensile test) using a thermal stress-strain measurement instrument “TMA/SS120C” manufactured by Seiko Instruments Inc. The measurement was performed during a temperature increase and during a temperature decrease in a temperature range of −50° C.→200° C. →−50° C. An average in a temperature range from 50° C. to 150° C. was determined. An adhesive strength between the polyimide film after curing and the copper foil was 0.24 kg/cm. The adhesive strength was evaluated by 90 degree peel test using a strip sample having a width of 5 mm.

### Example 2

First, 50.1 g (150 mmol) of 2,2′-bis(4-aminophenyl)hexafluoropropane (BIS-A-AF), 15.6 g (144 mmol) of p-phenylenediamine (PPD), and 1.49 g (6 0 mmol) of 1,3-bis(3-aminopropyl)tetramethyldisiloxane (APDS) were dissolved in 700 g of N-methylpyrrolidone, and 65.4 g (300 mmol) of pyromellitic dianhydride (PMDA) was then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 15.9%. Dimethylaminomethyl methacrylate, which is a photopolymerizable monomer, was mixed with the varnish in an amount of 1.2 equivalents relative to the carboxylic acid of the polyamic acid, and glycidyl methacrylate was mixed with the varnish in an amount of 4% relative to the total solid content of the varnish. In addition, as polymerization initiators, 2-benzyl-2-(dimethylamino)-1-[4-(4-morpholinyl)phenyl]-1-butanone and benzophenone were mixed with the varnish in amounts of 4% and 2%, respectively, relative to the total solid content of the varnish. Furthermore, benzenesulfonanilide was mixed with the varnish in an amount of 5% relative to the total solid content of the varnish. Thus, a negative photosensitive resin composition was prepared.

A polyimide resin film having a thickness after prebaking of 20 μm was prepared using the negative photosensitive resin composition by performing the same operation as that of Example 1 except that the light exposure was changed to 500 mJ/cm². A polyimide resin film in which a film loss did not substantially occur and which maintained a satisfactory development pattern was obtained. The polyimide film after curing had a thermal expansion coefficient of 21 ppm/° C. and a film-remaining ratio of 90%. The adhesive strength between the polyimide film after curing and the copper foil was 0.21 kg/cm.

### Example b 3

First, 43.2 g (135 mmol) of 2,2′-bis(trifluoromethyl)-4,4′-diaminobiphenyl (TFMB), 33.8 g (159 mmol) of 2,2′-dimethyl-4,4′-diaminobiphenyl (mTBHG), and 1.49 g (6.0 mmol) of 1,3-bis(3-aminopropyl)tetramethyldisiloxane (APDS) were dissolved in 700 g of N-methylpyrrolidone, and 44.2 g (150 mmol) of 3,4,3′,4′-biphenyltetracarboxylic dianhydride (BPDA) and 32.7 g (150 mmol) of pyromellitic dianhydride (PMDA) were then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 18.2%. Dimethylaminomethyl methacrylate, which is a photopolymerizable monomer, was mixed with the varnish in an amount of 1.2 equivalents relative to the carboxylic acid of the polyamic acid, and glycidyl methacrylate was mixed with the varnish in an amount of 4% relative to the total solid content of the varnish. In addition, as a polymerization initiator, 2-benzyl-2-(dimethylamino)-1-[4-(4-morpholinyl)phenyl]-1-butanone was mixed with the varnish in an amount of 4% relative to the total solid content of the varnish. Furthermore, benzenesulfonanilide was mixed with the varnish in an amount of 5% relative to the total solid content of the varnish. Thus, a negative photosensitive resin composition was prepared.

A resin film having a thickness after prebaking of 20 μm was prepared using the negative photosensitive resin composition by performing the same operation as that of Example 1 except that the light exposure was changed to 500 mJ/cm². A polyimide resin film in which a film loss did not substantially occur and which maintained a satisfactory development pattern was obtained. The polyimide film after curing had a thermal expansion coefficient of 18 ppm/° C. and a film-remaining ratio of 90%. The adhesive strength between the polyimide film after curing and the copper foil was 0.06 kg/cm.

### Example 4

First, 48.0 g (150 mmol) of 2,2′-bis(trifluoromethyl)-4,4′-diaminobiphenyl (TFMB) and 16.2 g (150 mmol) of p-phenylenediamine (PPD) were dissolved in 700 g of N-methylpyrrolidone, and 88.3 g (300 mmol) of 3,4,3′,4′-biphenyltetracarboxylic dianhydride (BPDA) was then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 16.2%. Dimethylaminomethyl methacrylate, which is a photopolymerizable monomer, was mixed with the varnish in an amount of 1.2 equivalents relative to the carboxylic acid of the polyamic acid, and glycidyl methacrylate was mixed with the varnish in an amount of 6% relative to the total solid content of the varnish. In addition, as polymerization initiators, 2-benzyl-2-(dimethylamino)-1-[4-(4-morpholinyl)phenyl]-1-butanone and bis(cyclopentadienyl)-bis[2,6-difluoro-3-(pyrr-1-yl)phenyl]titanium were mixed with the varnish in amounts of 4% and 2%, respectively, relative to the total solid content of the varnish. Furthermore, benzenesulfonanilide was mixed with the varnish in an amount of 5% relative to the total solid content of the varnish. Thus, a negative photosensitive resin composition was prepared.

A polyimide resin film having a thickness after prebaking of 20 μm was prepared using the negative photosensitive resin composition by performing the same operation as that of Example 1 except that the light exposure was changed to 500 mJ/cm². A film loss did not substantially occur, and a satisfactory development pattern was maintained. The polyimide film after curing had a thermal expansion coefficient of 17 ppm/° C. and a film-remaining ratio of 93%.

### Example 5

First, 41.7 g (114 mmol) of 2,2-bis(3-amino-4-hydroxyphenyl)hexafluoropropane (BIS-AP-AF), 38.2 g (180 mmol) of 2,2′-dimethyl-4,4′-diaminobiphenyl (mTBHG), and 1.49 g (6 0 mmol) of 1,3-bis(3-aminopropyl)tetramethyldisiloxane (APDS) were dissolved in 700 g of N-methylpyrrolidone, and 57.4 g (195 mmol) of 3,4,3′,4′-biphenyltetracarboxylic dianhydride (BPDA) and 22.9 g (105 mmol) of pyromellitic dianhydride (PMDA) were then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 18.9%. Dimethylaminomethyl methacrylate, which is a photopolymerizable monomer, was mixed with the varnish in an amount of 1.2 equivalents relative to the carboxylic acid of the polyamic acid, and glycidyl methacrylate was mixed with the varnish in an amount of 2% relative to the total solid content of the varnish. In addition, as a polymerization initiator, bis(cyclopentadienyl)-bis[2,6-difluoro-3-(pyrr-1-yl)phenyl]titanium was mixed with the varnish in an amount of 3% relative to the total solid content of the varnish. Thus, a negative photosensitive resin composition was prepared.

A polyimide resin film having a thickness after prebaking of 20 μm was prepared using the negative photosensitive resin composition by performing the same operation as that of Example 1 except that the light exposure was changed to 500 mJ/cm². A film loss did not substantially occur, and a satisfactory development pattern was maintained. The polyimide film after curing had a thermal expansion coefficient of 21 ppm/° C. and a film-remaining ratio of 91%. The adhesive strength between the polyimide film after curing and the copper foil was 0.2 kg/cm.

### Example 6

First, 35.5 g (120 mmol) of 2,2′-dimethyl-4,4′-diaminobiphenyl (mTBHG) and 19.4 g (180 mmol) of p-phenylenediamine (PPD) were dissolved in 700 g of N-methylpyrrolidone, and 44.2 g (150 mmol) of 3,4,3′,4′-biphenyltetracarboxylic dianhydride

(BPDA) and 32.7 g (150 mmol) of pyromellitic dianhydride (PMDA) were then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 16.5%. Dimethylaminomethyl methacrylate, which is a photopolymerizable monomer, was mixed with the varnish in an amount of 1.2 equivalents relative to the carboxylic acid of the polyamic acid, and allyl glycidyl ether was mixed with the varnish in an amount of 2% relative to the total solid content of the varnish. In addition, as a polymerization initiator, 2-benzyl-2-(dimethylamino)-1-[4-(4-morpholinyl)phenyl]-1-butanone (molar extinction coefficient at a wavelength of 365 nm: 1,500) was mixed with the varnish in an amount of 4% relative to the total solid content of the varnish. Thus, a negative photosensitive resin composition was prepared.

The negative photosensitive resin composition was applied onto a copper foil having a thickness of 40 μm by a spin-coating method, and was then dried by heating at 90° C. for 30 minutes to form a photosensitive polyimide precursor film having a thickness of 20 μm. Subsequently, the film was irradiated with ultraviolet light through a negative test pattern at a light exposure of 1,000 mJ/cm², and post-baking was then performed at 105° C. for 10 minutes. Subsequently, development was performed at 30° C. using an organic solvent developing solution. The film on the copper foil was sufficiently washed with distilled water, and was then forcibly dried in a nitrogen stream. Subsequently, heat treatment was performed at 120° C. for 30 minutes, at 220° C. for 30 minutes, and at 340° C. for 60 minutes in a nitrogen atmosphere to imidize the polyimide precursor. As a result, a polyimide resin film in which a film loss did not substantially occur and which maintained a satisfactory development pattern was obtained. The polyimide film after curing had a thermal expansion coefficient of 16 ppm/° C. and a film-remaining ratio of 89%. The adhesive strength between the polyimide film after curing and the copper foil was satisfactory; 0.48 kgf/cm.

### Example 7

First, 50.1 g (150 mmol) of 2,2′-bis(4-aminophenyl)hexafluoropropane (BIS-A-AF), 15.6 g (144 mmol) of p-phenylenediamine (PPD), and 1.49 g (6 0 mmol) of 1,3-bis(3-aminopropyl)tetramethyldisiloxane (APDS) were dissolved in 700 g of N-methylpyrrolidone, and 65.4 g (300 mmol) of pyromellitic dianhydride (PMDA) was then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 15.9%. Dimethylaminomethyl methacrylate, which is a photopolymerizable monomer, was mixed with the varnish in an amount of 1.2 equivalents relative to the carboxylic acid of the polyamic acid, and allyl glycidyl ether was mixed with the varnish in an amount of 4% relative to the total solid content of the varnish. In addition, as polymerization initiators, 2-benzyl-2-(dimethylamino)-1-[4-(4-morpholinyl)phenyl]-1-butanone and benzophenone were mixed with the varnish in amounts of 4% and 2%, respectively, relative to the total solid content of the varnish. Furthermore, benzenesulfonanilide was mixed with the varnish in an amount of 5% relative to the total solid content of the varnish. Thus, a negative photosensitive resin composition was prepared.

A polyimide resin film having a thickness after prebaking of 20 μm was prepared using the negative photosensitive resin composition by performing the same operation as that of Example 1 except that the light exposure was changed to 500 mJ/cm². A polyimide resin film in which a film loss did not substantially occur and which maintained a satisfactory development pattern was obtained. The polyimide film after curing had a thermal expansion coefficient of 21 ppm/° C. and a film-remaining ratio of 90%. The adhesive strength between the polyimide film after curing and the copper foil was satisfactory; 0.52 kgf/cm.

### Example 8

First, 43.2 g (135 mmol) of 2,2′-bis(trifluoromethyl)-4,4′-diaminobiphenyl (TFMB), 33.8 g (159 mmol) of 2,2′-dimethyl-4,4′-diaminobiphenyl (mTBHG), and 1.49 g (6.0 mmol) of 1,3-bis(3-aminopropyl)tetramethyldisiloxane (APDS) were dissolved in 700 g of N-methylpyrrolidone, and 44.2 g (150 mmol) of 3,4,3′,4′-biphenyltetracarboxylic dianhydride (BPDA) and 32.7 g (150 mmol) of pyromellitic dianhydride (PMDA) were then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 18.2%. Dimethylaminomethyl methacrylate, which is a photopolymerizable monomer, was mixed with the varnish in an amount of 1.2 equivalents relative to the carboxylic acid of the polyamic acid, and allyl glycidyl ether was mixed with the varnish in an amount of 4% relative to the total solid content of the varnish. In addition, as a polymerization initiator, 2-benzyl-2-(dimethylamino)-1-[4-(4-morpholinyl)phenyl]-1-butanone was mixed with the varnish in an amount of 4% relative to the total solid content of the varnish. Furthermore, benzenesulfonanilide was mixed with the varnish in an amount of 5% relative to the total solid content of the varnish. Thus, a negative photosensitive resin composition was prepared.

A resin film having a thickness after prebaking of 20 μm was prepared using the negative photosensitive resin composition by performing the same operation as that of Example 1 except that the light exposure was changed to 500 mJ/cm². A polyimide resin film in which a film loss did not substantially occur and which maintained a satisfactory development pattern was obtained. The polyimide film after curing had a thermal expansion coefficient of 18 ppm/° C. and a film-remaining ratio of 90%. The adhesive strength between the polyimide film after curing and the copper foil was satisfactory; 0.51 kgf/cm.

### Example 9

First, 48.0 g (150 mmol) of 2,2′-bis(trifluoromethyl)-4,4′-diaminobiphenyl (TFMB) and 16.2 g (150 mmol) of p-phenylenediamine (PPD) were dissolved in 700 g of N-methylpyrrolidone, and 88.3 g (300 mmol) of 3,4,3′,4′-biphenyltetracarboxylic dianhydride (BPDA) was then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 16.2%. Dimethylaminomethyl methacrylate, which is a photopolymerizable monomer, was mixed with the varnish in an amount of 1.2 equivalents relative to the carboxylic acid of the polyamic acid, and allyl glycidyl ether was mixed with the varnish in an amount of 6% relative to the total solid content of the varnish. In addition, as polymerization initiators, 2-benzyl-2-(dimethylamino)-1-[4-(4-morpholinyl)phenyl]-1-butanone and bis(cyclopentadienyl)-bis[2,6-difluoro-3-(pyrr-1-yl)phenyl]titanium were mixed with the varnish in amounts of 4% and 2%, respectively, relative to the total solid content of the varnish. Furthermore, benzenesulfonanilide was mixed with the varnish in an amount of 5% relative to the total solid content of the varnish. Thus, a negative photosensitive resin composition was prepared.

A polyimide resin film having a thickness after prebaking of 20 μm was prepared using the negative photosensitive resin composition by performing the same operation as that of Example 1 except that the light exposure was changed to 500 mJ/cm². A film loss did not substantially occur, and a satisfactory development pattern was maintained. The polyimide film after curing had a thermal expansion coefficient of 17 ppm/° C. and a film-remaining ratio of 93%. The adhesive strength between the polyimide film after curing and the copper foil was satisfactory; 0.43 kgf/cm.

### Comparative Example 1

First, 35.5 g (120 mmol) of 2,2′-dimethyl-4,4′-diaminobiphenyl (mTBHG) and 19.4 g (180 mmol) of p-phenylenediamine (PPD) were dissolved in 700 g of N-methylpyrrolidone, and 44.2 g (150 mmol) of 3,4,3′,4′-biphenyltetracarboxylic dianhydride (BPDA) and 32.7 g (150 mmol) of pyromellitic dianhydride (PMDA) were then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 16.5%. Dimethylaminomethyl methacrylate, which is a photopolymerizable monomer, was mixed with the varnish in an amount of 1.2 equivalents relative to the carboxylic acid of the polyamic acid. In addition, as a polymerization initiator, 2-benzyl-2-(dimethylamino)-1-[4-(4-morpholinyl)phenyl]-1-butanone was mixed with the varnish in an amount of 4% relative to the total solid content of the varnish. Thus, a negative photosensitive resin composition was prepared.

A polyimide resin film having a thickness after prebaking of 20 μm was prepared using the negative photosensitive resin composition as in Example 1. Cracks were formed in the photosensitive polyimide precursor film during the development. The polyimide film after curing had a thermal expansion coefficient of 15 ppm/° C. and a film-remaining ratio of 89%.

### Comparative Example 2

First, 50.1 g (150 mmol) of 2,2′-bis(4-aminophenyl)hexafluoropropane (BIS-A-AF), 15.6 g (144 mmol) of p-phenylenediamine (PPD), and 1.49 g (6 0 mmol) of 1,3-bis(3-aminopropyl)tetramethyldisiloxane (APDS) were dissolved in 700 g of N-methylpyrrolidone, and 65.4 g (300 mmol) of pyromellitic dianhydride (PMDA) was then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 15.9%. Dimethylaminomethyl methacrylate, which is a photopolymerizable monomer, was mixed with the varnish in an amount of 1.2 equivalents relative to the carboxylic acid of the polyamic acid. In addition, as polymerization initiators, 2-benzyl-2-(dimethylamino)-1-[4-(4-morpholinyl)phenyl]-1-butanone and bis(cyclopentadienyl)-bis[2,6-difluoro-3-(pyrr-1-yl)phenyl]titanium were mixed with the varnish in amounts of 4% and 2%, respectively, relative to the total solid content of the varnish. Furthermore, benzenesulfonanilide was mixed with the varnish in an amount of 5% relative to the total solid content of the varnish. Thus, a negative photosensitive resin composition was prepared.

A resin film having a thickness after prebaking of 20 μm was prepared using the negative photosensitive resin composition by performing the same operation as that of Example 1 except that the light exposure was changed to 500 mJ/cm². The film after curing was slightly detached from the copper foil. The polyimide film after curing had a thermal expansion coefficient of 25 ppm/° C. and a film-remaining ratio of 71%.

### Comparative Example 3

First, 43.2 g (135 mmol) of 2,2′-bis(trifluoromethyl)-4,4′-diaminobiphenyl (TFMB), 33.8 g (159 mmol) of 2,2′-dimethyl-4,4′-diaminobiphenyl (mTBHG), and 1.49 g (6.0 mmol) of 1,3-bis(3-aminopropyl)tetramethyldisiloxane (APDS) were dissolved in 700 g of N-methylpyrrolidone, and 44.2 g (150 mmol) of 3,4,3′,4′-biphenyltetracarboxylic dianhydride (BPDA) and 32.7 g (150 mmol) of pyromellitic dianhydride (PMDA) were then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 18.2%. Dimethylaminomethyl methacrylate, which is a photopolymerizable monomer, was mixed with the varnish in an amount of 1.2 equivalents relative to the carboxylic acid of the polyamic acid. In addition, as a polymerization initiator, 2-benzyl-2-(dimethylamino)-1-[4-(4-morpholinyl)phenyl]-1-butanone was mixed with the varnish in an amount of 4% relative to the total solid content of the varnish. Furthermore, benzenesulfonanilide was mixed with the varnish in an amount of 5% relative to the total solid content of the varnish. Thus, a negative photosensitive resin composition was prepared.

A resin film having a thickness after prebaking of 20 μm was prepared using the negative photosensitive resin composition by performing the same operation as that of Example 1 except that the light exposure was changed to 500 mJ/cm². A large amount of film loss was observed in the resulting polyimide film, and cracks were also formed in a portion of the polyimide film. The polyimide film after curing had a thermal expansion coefficient of 18 ppm/° C. and a film-remaining ratio of 70%.

### Comparative Example 4

First, 48.0 g (150 mmol) of 2,2′-bis(trifluoromethyl)-4,4′-diaminobiphenyl (TFMB) and 16.2 g (150 mmol) of p-phenylenediamine (PPD) were dissolved in 700 g of N-methylpyrrolidone, and 88.3 g (300 mmol) of 3,4,3′,4′-biphenyltetracarboxylic dianhydride (BPDA) was then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 16.2%. Dimethylaminomethyl methacrylate, which is a photopolymerizable monomer, was mixed with the varnish in an amount of 1.2 equivalents relative to the carboxylic acid of the polyamic acid. In addition, as polymerization initiators, 2-benzyl-2-(dimethylamino)-1-[4-(4-morpholinyl)phenyl]-1-butanone and bis(cyclopentadienyl)-bis[2,6-difluoro-3-(pyrr-1-yl)phenyl]titanium were mixed with the varnish in amounts of 4% and 2%, respectively, relative to the total solid content of the varnish. Furthermore, benzenesulfonanilide was mixed with the varnish in an amount of 5% relative to the total solid content of the varnish. Thus, a negative photosensitive resin composition was prepared.

A polyimide resin film having a thickness after prebaking of 20 μm was prepared using the negative photosensitive resin composition by performing the same operation as that of Example 1 except that the light exposure was changed to 500 mJ/cm². Detachment of the polyimide film after curing was microscopically observed, and a sufficient adhesive strength to the copper foil could not be obtained. The polyimide film after curing had a thermal expansion coefficient of 15 ppm/° C. and a film-remaining ratio of 78%.

### Comparative Example 5

First, 41.7 g (114 mmol) of 2,2-bis(3-amino-4-hydroxyphenyl)hexafluoropropane (BIS-AP-AF), 38.2 g (180 mmol) of 2,2′-dimethyl-4,4′-diaminobiphenyl (mTBHG), and 1.49 g (6 0 mmol) of 1,3-bis(3-aminopropyl)tetramethyldisiloxane (APDS) were dissolved in 700 g of N-methylpyrrolidone, and 57.4 g (195 mmol) of 3,4,3′,4′-biphenyltetracarboxylic dianhydride (BPDA) and 22.9 g (105 mmol) of pyromellitic dianhydride (PMDA) were then added to the solution. The resulting mixture was stirred in a nitrogen atmosphere at room temperature for one hour. The mixture was then stirred at 60° C. for 20 hours, and the reaction was terminated. The solid content of the synthesized copolymerization varnish was 18.9%. Dimethylaminomethyl methacrylate, which is a photopolymerizable monomer, was mixed with the varnish in an amount of 1.2 equivalents relative to the carboxylic acid of the polyamic acid. In addition, as a polymerization initiator, bis(cyclopentadienyl)-bis[2,6-difluoro-3-(pyrr-1-yl)phenyl]titanium was mixed with the varnish in an amount of 3% relative to the total solid content of the varnish. Thus, a negative photosensitive resin composition was prepared.

A polyimide resin film having a thickness after prebaking of 20 μm was prepared using the negative photosensitive resin composition by performing the same operation as that of Example 1 except that the light exposure was changed to 500 mJ/cm². The film-remaining ratio of the polyimide film was 70%, and thus the film loss was large. The polyimide film hardly remained in minute portions of the pattern. The polyimide film after curing had a thermal expansion coefficient of 18 ppm/° C.

The above results show that, in Examples 1 to 9, which contains a compound having a photoreactive functional group and a glycidyl group (glycidyl methacrylate or allyl glycidyl ether) as a photopolymerizable monomer, it is possible to obtain polyimide resin films whose degradation by a developing solution is suppressed and which have a high film-remaining ratio. Furthermore, Examples 6 to 9, in which allyl glycidyl ether is used, exhibit excellent adhesiveness between the polyimide film and the copper foil, and thus can achieve both a satisfactory developing property and a high adhesiveness.

### INDUSTRIAL APPLICABILITY

The present invention can be suitably used in a negative photosensitive resin composition in which non-exposed areas have excellent solubility in a developing solution, and degradation of a film located in exposed areas, the degradation being caused by the developing solution, is suppressed. The present invention can be suitably used in a printed circuit board and a polyimide resin film using the negative photosensitive resin composition.

### CITATION LIST

### Patent Literature

PTL 1: Japanese Unexamined Patent Application Publication No. 54-145794
PTL 2: Japanese Examined Patent Application Publication No. 55-41422
PTL 3: Japanese Unexamined Patent Application Publication No. 10-265572

1. A negative photosensitive resin composition comprising a polyimide precursor resin obtained by condensation polymerization of a carboxylic anhydride component containing an aromatic tetracarboxylic dianhydride and a diamine component containing an aromatic diamine; at least one photopolymerizable monomer; and a photopolymerization initiator, wherein a compound having a photoreactive functional group and a glycidyl group is contained as the at least one photopolymerizable monomer in an amount of 0.05% to 15% by weight relative to the total solid content of the negative photosensitive resin composition.

2. The negative photosensitive resin composition according to claim 1, wherein a compound having a photoreactive functional group and an amino group is further contained as the at least one photopolymerizable monomer.

3. The negative photosensitive resin composition according to claim 1, wherein the compound having a photoreactive functional group and a glycidyl group is at least one selected from the group consisting of glycidyl methacrylate, glycidyl acrylate, allyl glycidyl ether, and 4-hydroxybutyl acrylate glycidyl ether.

4. The negative photosensitive resin composition according to claim 1, wherein the polyimide precursor resin is obtained by condensation polymerization of an aromatic tetracarboxylic dianhydride and two or more diamines, and a fluorinated monomer is contained as the diamine component in an amount of 30% by mole or more and 70% by mole or less relative to the total amount of the diamines.

5. A polyimide resin film obtained by applying the negative photosensitive resin composition according to claim 1 onto a base, and curing the negative photosensitive resin composition by heating.

6. The polyimide resin film according to claim 5, having a thermal expansion coefficient of 10 ppm/° C. or more and 30 ppm/° C. or less.

7. A flexible printed circuit board comprising the polyimide resin film according to claim 6 as a protective film.

8. The flexible printed circuit board according to claim 7, used as a substrate for a suspension used in a hard disk drive.
